(19) United States
(12) Patent Application Publication
(10) Pub. No.: US 2007/0045829 A1
(43) Pub. Date: Mar. 1, 2007

(54) Backside ground type flip chip semiconductor package

(75) Inventors: In Ho Jeong, Daejeon (KR); Nam Heung Kim, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/510,649

(22) Filed: Aug. 28, 2006

(30) Foreign Application Priority Data
Aug. 30, 2005 (KR) 10-2005-80310

(51) Int. Cl. H01L 23/34

(52) U.S. Cl. 257/723

(57) ABSTRACT

In a flip chip semiconductor package, a substrate is provided. At least one chip is flip-bonded onto the substrate to electrically connect to a circuit pattern-printed on the substrate. A molded part is formed on the substrate so as to expose a backside ground of the chip. Also, a conductive metal layer is extended along an outer surface of the molded part to electrically connect to the backside ground. According to the invention, heat generated from the chip is released through the backside ground to improve heat releasing properties. Furthermore, the electrical ground is formed without creating a parasitic component to enhance electrical properties.

### CLAIM OF PRIORITY

This application claims the benefit of Korean Patent Application No. 2005-80310 filed on Aug. 30, 2005 in the Korean Intellectual Property Office, the disclosure of which is incorporated herein by reference.

### BACKGROUND OF THE INVENTION

1. Field of the Invention

The present invention relates to a flip chip semiconductor package having a backside ground and more particularly, a backside flip chip semiconductor package which releases heat generated from a chip through a backside ground to improve heat releasing properties and has the electrical ground formed free from a parasitic component to enhance electrical properties.

2. Description of the Related Art

With recent advancement in personal mobile telecommunications, a great number of devices or parts have been highly dense and multi-functional, especially buoyed by development of softwares and techniques of IC integration. Most strikingly, not only each part or block but also an overall system tends to be modularized.

Such modularization requires various types of substrates or packages to increase density, as exemplified by a flip chip package or a wafer-level chip scale package.

This flip-chip package exhibits higher electrical properties than a package in which an IC chip is wire bonded onto a substrate via a plurality of metal wires in terms of electrical properties. That is, the flip-chip package lowers parasitic inductance. Also, a foot-print area corresponding to a top surface of the substrate can be reduced to a chip size, thereby proving spatially beneficial in modularization. Consequently the flip-chip package is considerably utilized in products requiring high-density modularization and a plurality of input and output pins. Moreover, the flip-chip package is employed to reduce size and thickness of a single IC product.

FIGS. 1a to 1c are cross-sectional views illustrating various types of a conventional semiconductor package. As shown in FIGS. 1a to 1c, variously-sized chips 10 and 20 are flip-bonded onto a substrate 1 via bump balls 11. Alternatively, the chips 10 and 20 are wire bonded onto a predetermined area of the substrate via a plurality of metal wires 21. The substrate 1 has various types of parts 2 mounted thereon together with the chips 10 and 20.

Alternatively, one 20 of the chips is wire-bonded onto the substrate 1 for a lower part and the other one 10 of the chips is flip-bonded onto the chip 20 for an upper part, thereby stacked vertically.

As shown in FIGS. 1a and 1b, the substrate 1, which has the chips 10 and 20 mounted thereover, also has an encapsulant or molded part 3 formed of resin to protect the mounting parts from external environment. Alternatively, as shown in FIG. 1c, the substrate 1 has a top surface fixed to an underside surface of a metal can 4.

The flip chip bonding is chiefly used in signal processing and a low power device of hundreds of mW or less such as a dried terminal of a receiver or a transmitter. Therefore, heat generated from the flip-bonded chip 10 is not a big factor in its operation.

Furthermore, heat generated from the chips 10 and 20 is released to the outside through the bump balls 11, molded part 3 or a heat-releasing via structure 5 disposed under the chip, thereby not degrading properties due to heat.

Meanwhile, in a case where the flip bonded chip 10 is employed in a high power device of hundreds of mW or more such as a power amplifier, as shown in FIGS. 1a and 1c, a backside ground electrode 15 formed on the backside of the chip 10 is electrically connected to the bump balls 11 by a wafer through via hole process. Also, the substrate 1 has another heat-releasing via structure 6 formed therein and has a path for releasing heat to the outside. The heat-releasing via structure 6 has an upper end contacting the bump balls and a lower end contacting a heat releasing layer 7 formed underneath the substrate 1.

However, the path fails to enable heat generated from the chip 10 to be entirely released to the outside, thereby limitedly enhancing thermal properties of the package product.

In addition, as shown in FIGS. 1a to 1c, in the wire-bonded chip 20, the backside ground electrode 25 facing downward, and opposing the substrate 1 is electrically connected to the via structure 5 formed in the substrate via a die patch and grounded. On the other hand, in the flip chip bonded chip 10, a backside ground electrode 15 facing upward is electrically connected to a via structure 6 formed in the substrate by a wafer through via structure (not illustrated) formed inside the chip and the bump balls 11, and then grounded.

Accordingly, the backside ground electrode 15 of the flip bonded chip 10 has additional paths such as the wafer through via structure (not illustrated) and bump balls 11. This increases parasitic capacitance, thereby disadvantageously deteriorating electrical properties of the product.

Moreover, in a case where the backside ground electrode 15 of the flip bonded chip 10 is not ground to the substrate 1, a high-frequency signal from the chip 10 affects other adjacent chip components through the backside ground electrode 15, potentially generating noises induced by external radio wave. As a result, the chip which exhibits sensitive properties and a high available frequency, and processes a high-power signal maybe jeopardized by heat releasing problems, radio wave radiation and radio wave noises.

### SUMMARY OF THE INVENTION

The present invention has been made to solve the foregoing problems of the prior art and therefore an object according to certain embodiments of the present invention is to provide a backside ground flip chip semiconductor package which releases heat generated from a chip through a backside ground to improve heat releasing properties.

Another object according to certain embodiments of the invention is to provide a backside ground flip chip semiconductor package which has an electrical ground formed free from a parasitic component to enhance electrical properties.

Another object according to certain embodiments of the invention is to provide a backside ground flip chip semiconductor package which prevents internal radio wave from a chip from being emanated outside to interfere with a signal, and external wave from being induced inside the chip.

According to an aspect of the invention for realizing the object, there is provided a flip chip semiconductor package including a substrate; at least one chip flip-bonded onto the substrate to electrically connect to a circuit pattern-printed on the substrate; a molded part formed on the substrate so as to expose a backside ground of the chip; and a conductive metal layer extended along an outer surface of the molded part to electrically connect to the backside ground.

Preferably, the substrate comprises at least one heat-releasing via structure having a top surface connected to a bump ball where the chip is flip-bonded; and a metal connecting pad connected to an underside surface of the light releasing via structure.

Preferably, the substrate has at least one lower ground pad provided on an underside thereof, the lower ground pad grounded to the conductive metal layer.

More preferably, the lower ground pad is electrically connected to a ground terminal of a main substrate in a position where the substrate is mounted on the main substrate.

Preferably, the substrate has at least one upper ground pad grounded to the conductive metal layer, wherein the upper ground pad is connected to a top surface of at least one ground via structure formed in the substrate, and wherein the ground via structure has an underside surface connected to a metal connecting pad provided on an underside of the substrate.

More preferably, the metal connecting pad is connected to a lower end of at least one heat-releasing via structure formed in the substrate.

More preferably, the metal connecting pad is connected to an electrode of a main substrate in a position where the substrate is mounted on the main substrate.

Preferably, the molded part is formed coplanar with the backside ground so as to expose the backside ground to the outside.

Preferably, the molded part is formed higher than the backside ground so as to expose the backside ground to the outside.

Preferably, the molded part is formed higher than the backside ground and has an opening for exposing the backside ground to the outside.

More preferably, the opening is smaller than the backside ground.

Preferably, the molded part is formed higher than an underside surface of the chip and lower than a top surface of the chip so as to expose the backside ground to the outside.

More preferably, the molded part comprises an adhesive material.

More preferably, the adhesive material comprises one selected from a group consisting of anisotropic conductive film (ACF), non-conductive film (NCF), anisotropic conductive paste (ACP) and non-conductive paste (NCP).

Preferably, the conductive metal layer is formed via sputtering or evaporation.

Preferably, the conductive metal layer is formed via electrolysis plating or electroless plating.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1c are cross-sectional views illustrating various types of a conventional semiconductor package;

FIG. 2 is a cross-sectional view illustrating a first embodiment of a backside ground flip chip semiconductor package according to the invention;

FIGS. 3a to 3g are procedural flow charts illustrating a first embodiment of a backside ground flip chip semiconductor package according to the invention;

FIG. 4 is a cross-sectional view illustrating a second embodiment of a backside ground flip chip semiconductor package according to the invention;

FIGS. 5a to 5f are cross-sectional views illustrating a process according to the second embodiment of the backside ground flip chip semiconductor package;

FIG. 6 is a cross-sectional view illustrating a third embodiment of a backside ground flip chip semiconductor package according to the invention; and

FIG. 7 is a cross-sectional view illustrating a fourth embodiment of a backside ground flip chip semiconductor package according to the invention.

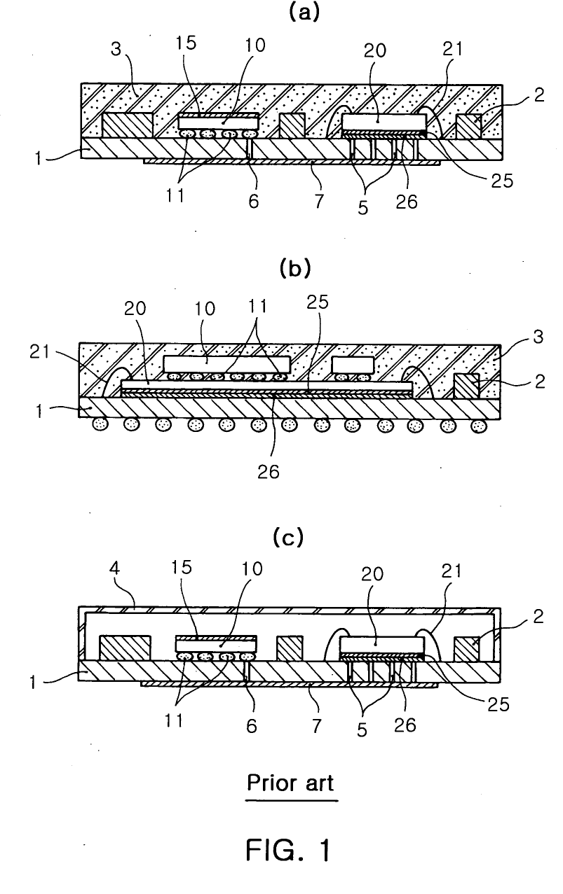

### DETAILED DESCRIPTION OF THE PREFERRED EMBODIMENT

Preferred embodiments of the present invention will now be described in detail with reference to the accompanying drawings.

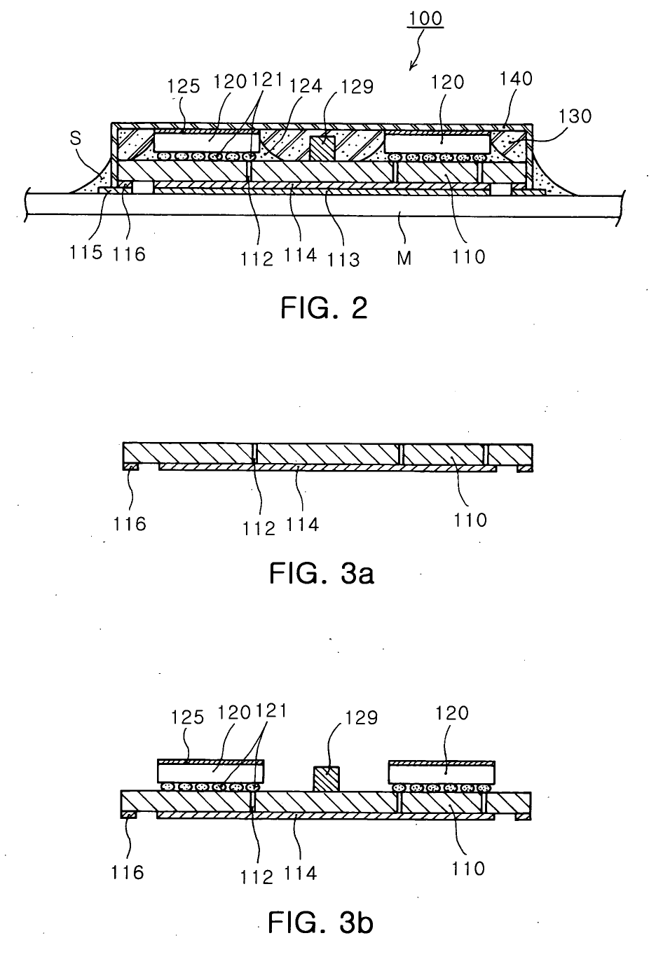

FIG. 2 is a cross-sectional view illustrating a first embodiment of a backside ground flip chip semiconductor package. The flip chip semiconductor package of the invention, as shown in FIG. 2, has a heat releasing path connected to a main substrate via a backside ground electrode and a ground path connected to the main substrate. The flip chip semiconductor package includes a substrate 110, a chip 120, an encapsulant or molded part 130 and a conductive metal layer 140.

The substrate 110 has various circuits pattern-printed thereon and at least one chip 120 and a passive device 129 mounted thereover to suit the circuits.

The substrate 110 has at least one heat-releasing via structure 112 connected to a metal connecting pad 114 provided on an underside of the substrate 110. At least one lower ground pad 116 is disposed in the vicinity of the metal connecting pad 114.

The chip 120 has a plurality of ball pads (not illustrated) arrayed on an underside surface thereof at a predetermined gap. The ball pads of the chip 120 serve as a chip component flip-bonded onto the substrate 110 via a plurality of bump balls 121 to electrically connect to the substrate 110.

Here, the bump balls 121 are connected to an upper end of the heat-releasing via structure 112. Also, the heat-releasing via structure 112 has a lower end connected to the metal connecting pad 114 provided on the underside of the substrate 110. The metal connecting pad 114 contacts a connecting pad 113 of the main substrate M in a position where the substrate 110 is mounted on the main substrate M.

Accordingly, heat generated from the chip 120 is released via a path leading toward the main substrate M through the heat-releasing via structure 112, the metal connecting pad 114 and the connecting pad 113.

A lower ground pad 116 provided on the underside surface of the substrate 110 is electrically connected to a ground terminal 115 of the main substrate M in a position where the substrate 110 is mounted on the main substrate M.

As a result, the chip 120 flip-bonded has a ground path in which the backside ground electrode 125 facing upward is connected to the main substrate M via the conductive metal layer 140, the lower ground pad 116, and the ground terminal 115.

In addition, the substrate 110 has a molded part 130 formed thereon to protect the chip 120 and a surrounding passive device 129 from external environment. The molded part 130 is formed of resin such as epoxy.

Here, in one of the methods to expose the backside ground electrode 125 of the chip 120 to the outside, preferably, the molded part 130 is formed coplanar with the backside ground electrode 125.

Also, in a case where the molded part 130 entirely encapsulates the chip 120 including the backside ground electrode 125, a top surface of the molded part 130 is polished so as to expose the backside ground electrode 125 to the outside.

Here, in order to maximally expose the backside ground electrode 125, the molded part 130 may be polished up to an underside surface of the backside ground electrode 125.

The conductive metal layer 140 is formed to expose the backside ground electrode 125 to the outside so that the backside ground electrode 125 of the chip 120 is electrically connected to the main substrate M. Alternatively, the conductive metal layer 140 is extended along an outer surface of the molded part 130 to a predetermined thickness.

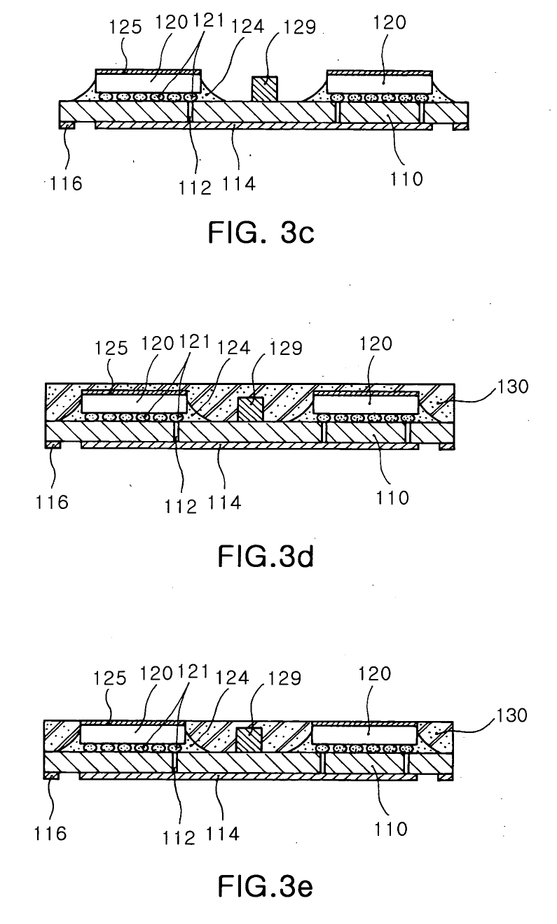

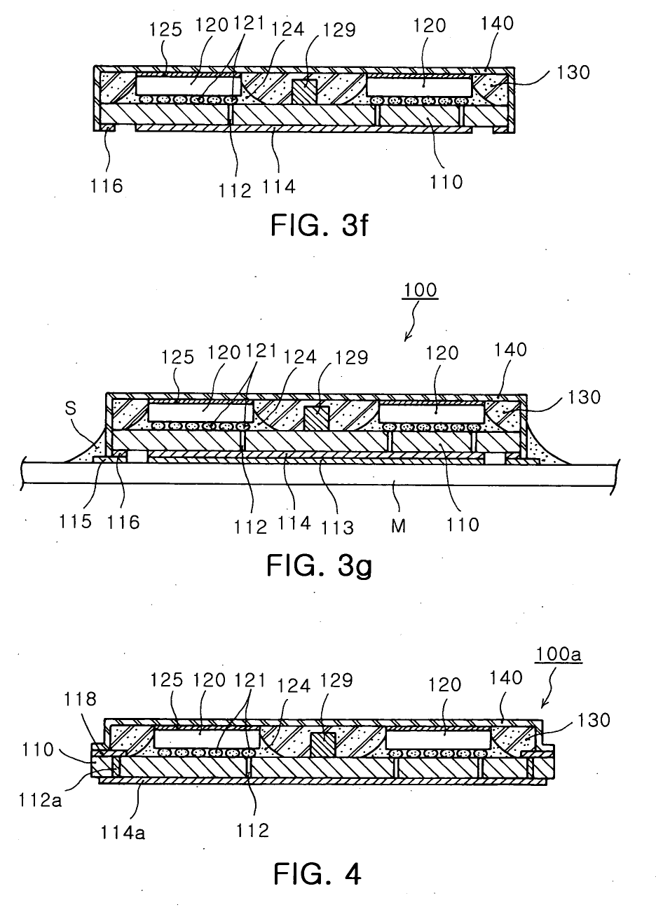

According to a process for manufacturing a backside ground flip chip semiconductor package of a first embodiment of the invention, a substrate 110 is prepared, in which a heat-releasing via structure 112, a metal connecting pad 114 and a lower ground pad 116 are formed. At least one chip 120 is flip-bonded onto the substrate 110 via a plurality of bump balls 121 to suit circuits pattern-printed on the substrate 110. Also, at least one passive device 129 is mounted near the chip 120 (See FIGS. 3a and 3b).

Here, one of the bump balls 121 is disposed corresponding to the via structure 112 to ensure heat generated from the chip to be released through the heat-releasing via structure 112.

Furthermore, as shown in FIG. 3c, the chip 120 flip-bonded onto the substrate 110 has an underfiller 124 filled between an underside thereof and the substrate 110. As shown in FIGS. 3d and 3e, a molded part is formed to encapsulate the chip 120 and the passive device mounted over the substrate 110, thereby protecting them from external environment.

Here, in a case where the molded part 130 is formed higher than the backside ground electrode 125, a top surface of the molded part 130 is polished to expose the backside ground electrode 125 to the outside.

In addition, in a case where the molded part 130 is formed coplanar with the backside ground electrode 125, the backside ground electrode 125 is exposed to the outside through the molded part 130.

Subsequently, as shown in FIG. 3f, the molded part 130 has a conductive metal layer 140 extended along an outer surface thereof. To form the conductive metal layer 140, a conductive metal material is grown to a predetermined thickness by a semiconductor-based process such as sputtering and evaporation.

That is, preferably the conductive metal layer 140 is selectively made of a metal having superior electrical and thermal conductivity such as gold, silver, copper and aluminum. Also, the metal is deposited via metal evaporation in which a metal lump is placed into an evaporator, heated and liquefied via e-beam or current and then vaporized.

Alternatively, the conductive metal layer 140 for the backside ground electrode is obtained via sputtering, in which plasma is formed in a metal target made of e.g., gold, silver, copper and aluminum to deposit the metal.

Alternatively, besides such a semiconductor-based process, the metal layer for the backside ground electrode is formed by plating using simple equipment and apparatuses. Here, electrolysis plating and electroless plating may be adopted. In the former process, a seed metal such as gold and copper is formed on a surface of the molded part and electricity is applied to an electrolysis solution to plate gold or copper. In the latter process, the metal is plated via ion combination without using electricity.

Here, the electroless plating necessitates the use of a catalyst such as palladium, which belongs to a conventional plating process.

Preferably, the conductive metal layer 140 is extended along an outer surface of the molded part 130, and has a lower end contacting a lower ground pad 116 provided on the underside of the substrate 110.

Moreover, as shown in FIG. 3g, the heat-releasing via structure 112 of the substrate 110 and the metal connecting pad 114 are bonded to the connecting pad of a main substrate M in a position where the substrate 110 with the conductive metal layer 140 formed therein is mounted on the main substrate M. This produces a heat releasing path for releasing heat generated from the chip toward the substrate 110.

Also, the conductive metal layer 140 is electrically connected to the ground terminal 115 of the main substrate M via a solder S. This produces a ground path which leads from the conductive metal layer 140 to the ground terminal 115 without passing through the chip, thereby preventing occurrence of a parasitic component.

The conductive metal layer 140 and the ground terminal 115 allow an entire outer surface of the molded part 130 to serve as a ground area. Accordingly, this prevents a signal generated from the chip 120 from being radiated to the outside to interfere with a signal from an adjacent chip, and an external signal from being induced inside.

FIG. 4 is a cross-sectional view illustrating a second embodiment of a backside ground flip chip semiconductor package according to the invention. The package 100a of the invention, as shown in FIG. 4, includes a substrate 110, a chip 120, a molded part 130 and a conductive metal layer 140. Therefore, the same components were given the same reference signs and will not be explained further.

The substrate 110 has a heat-releasing via structure 112 and a ground via structure 112a formed therein. The heat-releasing via structure 112 has an upper end connected to bump balls 121 on which the chip 120 is flip-bonded. The ground via structure 112a has an upper end connected to an upper ground pad 118 formed on the substrate 110.

The heat-releasing via structure 112 and the ground via structure 112a each has a lower end connected to a metal connecting pad 114a provided on an underside of the substrate 110. The metal connecting pad 114a is electrically connected to an electrode of the main substrate in a position where the substrate 110 is mounted on the main substrate M.

The conductive metal layer 140 is electrically connected to a backside ground electrode 125. Also, the conductive metal layer 140 is extended along an outer surface of the molded part 130 to electrically connect to the upper ground pad 118 of the substrate 110. This produces a ground path leading from the backside ground electrode 125, the conductive metal layer 140, the upper ground pad 118, the ground via structure 112a, and the metal connecting pad 114a to the main substrate M.

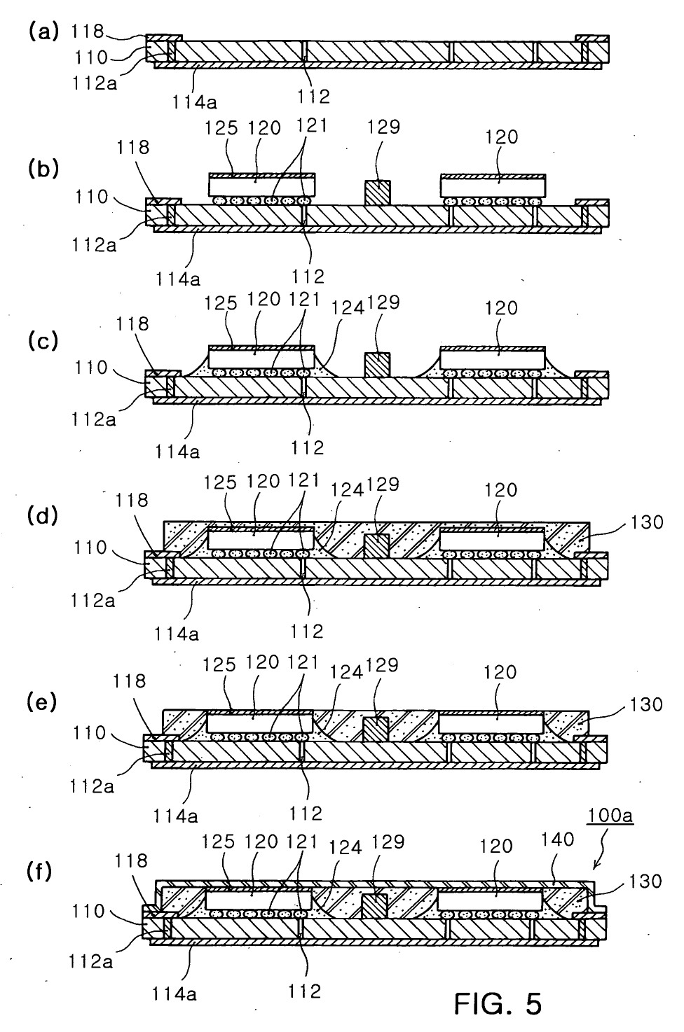

According to a process for manufacturing a backside ground flip chip semiconductor package of the second embodiment of the invention, a substrate 110 is provided, in which a heat-releasing via structure 112, a ground via structure 112a, a metal connecting pad 114 and an upper ground pad 118 are formed. At least one chip 120 is flip-bonded onto the substrate 110 via a plurality of bump balls 121. Also, at least one passive device 129 is mounted in the vicinity of the chip 120. (See FIGS. 5a and 5b)

One of the bump balls 121 is connected to an upper end of the heat-releasing via structure 112 and the upper ground pad 118 is connected to an upper end of the ground via structure 112a.

Also, as shown in FIGS. 5c and 5d, an underfiller 124 is filled between the substrate 110 and the chip 120 flip-bonded thereonto. Then a molded part 130 is formed to encapsulate the chip 120 and the passive device 129, thereby protecting them from external environment. Here, the molded part 130 is formed to expose the upper ground pad 118 from an outer side thereof.

In a case where the molded part 130 is formed higher than a backside ground electrode 125 of the chip, as shown in FIG. 5e, a top surface of the molded part 13 is polished to expose the backside ground electrode 125 to the outside.

In a case where the molded part 130 is formed coplanar with the backside ground electrode 125, the backside ground electrode 125 is exposed to the outside via the molded part 130 as shown in FIG. 5e.

Subsequently, a conductive metal material is formed to a predetermined thickness on an outer surface of the molded part 130 via CVD, sputtering and evaporation to obtain a conductive metal layer 140, as shown in FIG. 5f.

The conductive metal layer 140 is extended along the outer surface of the molded part 130. Preferably, the conductive metal layer 140 has a lower end contacting the upper ground pad 118 formed on the substrate 110.

A metal connecting pad 114a connected to the heat-releasing via structure 112 and the ground via structure 112a of the substrate 110 is connected to an electrode of the main substrate M in a position where the package 110a having the backside ground electrode 125 connected to the conductive metal layer 140 is mounted on the main substrate M. This produces a heat releasing path for releasing heat generated from the chip toward the substrate 110, and also a ground path.

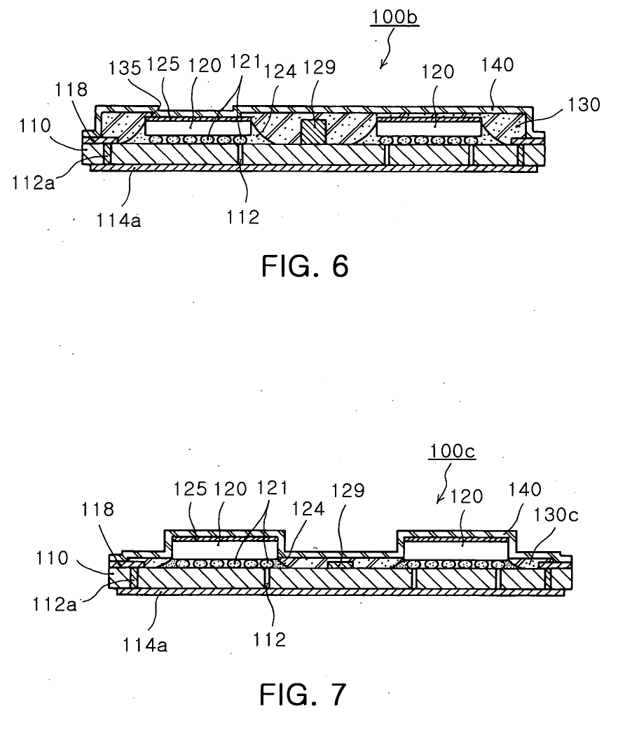

FIG. 6 is a cross-sectional view illustrating a third embodiment of a backside ground flip chip semiconductor according to the invention. The package 100b of the invention includes a substrate 110, a chip 120, a molded part 130 and a metal conductive layer 140. The same components were given the same reference signs and will not be explained further.

In a case where the molded part 130 is formed higher than a backside ground electrode 125 of the chip, the molded part 130 has an opening 135 for exposing the backside ground electrode 125 to the outside, corresponding to the backside ground electrode 125. The opening 135 is smaller than the backside ground electrode 125.

Accordingly, such a molded part 130 has a greater height than a molded part formed upto the backside ground electrode 125 and then polished, thereby leading to a bigger size of the product. However, the molded part 130 structured as just described further ensures the chip to be protected from external environment, thereby boosting reliability of the product.

Moreover, another chip 120, which uses the backside ground electrode 125 without requiring a ground path may be installed on the substrate 110 to produce a package.

FIG. 7 is a cross-sectional view illustrating a fourth embodiment of a backside ground flip chip semiconductor package according to the invention. The package 100c includes a substrate 110, a chip 120, a molded part 130c and a conductive metal layer 140. The same components were given the same reference signs and will not be explained further.

The molded part 130c is formed higher than an underside surface of the chip 120 and lower than a top surface thereof to expose to the outside a backside ground electrode 125 of the chip flip bonded onto the substrate.

In order to be more highly bonded to an upper ground pad 118 of the substrate 110, the molded part 130c is made of an adhesive material selected from a group consisting of anisotropic conductive film (ACF), non-conductive film (NCF), anisotropic conductive paste (ACP) and non-conductive paste (NCP).

Accordingly, the molded part 130c made of the adhesive material and formed lower than the top surface of the chip 120 as just described, is more highly bonded to the upper ground pad, resulting in better grounding capability. This also reduces the package size, thereby contributing to miniaturization thereof.

In addition, the chip exposed to the outside from the molded part 130c is protected from external environment by the conductive metal layer 140.

As set forth above, according to preferred embodiments of the invention, a molded part is formed to encapsulate a chip flip-bonded onto a substrate and a conductive metal layer is extended along an outer surface of the molded part to electrically connect to a backside ground electrode of the chip. This produces a ground path connected via the conductive metal layer without passing through the chip, thereby operating the chip free from a parasitic component and thus elevating reliability of the product.

Furthermore, heat generated from the chip is released to the outside through the conductive metal layer extended along the outer surface of the molded part and a heat-releasing via structure formed on the substrate. This improves heat releasing properties of the product.

Also, the conductive metal layer extended along the outer surface of the molded part can serve as a ground area. This improves grounding capability of the product and more blocks harmful electromagnetic wave from being induced from outside, thereby bolstering reliability of the product.

In addition, the invention fundamentally blocks a signal generated from a chip from being radiated unnecessarily to the outside to interfere with a signal from an adjacent chip, and an external harmful signal from being induced inside the chip. Consequently this increases electrical properties of the product.

A molded part is formed higher than a backside ground so as to expose the backside ground, thereby allowing the chip to be electrically influenced to a minimum extent by external environment and thus stably maintaining electrical properties of the product.

Moreover, the molded part is made of an adhesive material and formed lower than the chip to be more highly bonded to a ground pad, also reducing a height of the package. This advantageously enhances grounding capability and enables miniaturization of the product.

While the present invention has been shown and described in connection with the preferred embodiments, it will be apparent to those skilled in the art that modifications and variations can be made without departing from the spirit and scope of the invention as defined by the appended claims.

What is claimed is:

1. A flip chip semiconductor package comprising:
a substrate;
at least one chip flip-bonded onto the substrate to electrically connect to a circuit pattern-printed on the substrate;
a molded part formed on the substrate so as to expose a backside ground of the chip; and
a conductive metal layer extended along an outer surface of the molded part to electrically connect to the backside ground.

2. The flip chip semiconductor package according to claim 1, wherein the substrate comprises:
at least one heat-releasing via structure having a top surface connected to a bump ball where the chip is flip-bonded; and
a metal connecting pad connected to an underside surface of the light releasing via structure.

3. The flip chip semiconductor package according to claim 1, wherein the substrate has at least one lower ground pad provided on an underside thereof, the lower ground pad grounded to the conductive metal layer.

4. The flip chip semiconductor package according to claim 3, wherein the lower ground pad is electrically connected to a ground terminal of a main substrate in a position where the substrate is mounted on the main substrate.

5. The flip chip semiconductor package according to claim 1, wherein the substrate has at least one upper ground pad grounded to the conductive metal layer,
wherein the upper ground pad is connected to a top surface of at least one ground via structure formed in the substrate, and
wherein the ground via structure has an underside surface connected to a metal connecting pad provided on an underside of the substrate.

6. The flip chip semiconductor package according to claim 5, wherein the metal connecting pad is connected to a lower end of at least one heat-releasing via structure formed in the substrate.

7. The flip chip semiconductor package according to claim 5, wherein the metal connecting pad is connected to an electrode of a main substrate in a position where the substrate is mounted on the main substrate.

8. The flip chip semiconductor package according to claim 1, wherein the molded part is formed coplanar with the backside ground so as to expose the backside ground to the outside.

9. The flip chip semiconductor package according to claim 1, wherein the molded part is formed higher than the backside ground so as to expose the backside ground to the outside.

10. The flip chip semiconductor package according to claim 1, wherein the molded part is formed higher than the backside ground and has an opening for exposing the backside ground to the outside.

11. The flip chip semiconductor package according to claim 10, wherein the opening is smaller than the backside ground.

12. The flip chip semiconductor package according to claim 1, wherein the molded part is formed higher than an underside surface of the chip and lower than a top surface of the chip so as to expose the backside ground to the outside.

13. The flip chip semiconductor package according to claim 12, wherein the molded part comprises an adhesive material.

14. The flip chip semiconductor package according to claim 13, wherein the adhesive material comprises one selected from a group consisting of anisotropic conductive film (ACF), non-conductive film (NCF), anisotropic conductive paste (ACP) and non-conductive paste (NCP).

15. The flip chip semiconductor package according to claim 1, wherein the conductive metal layer is formed via sputtering or evaporation.

16. The flip chip semiconductor package according to claim 1, wherein the conductive metal layer is formed via electrolysis plating or electroless plating.

17. The flip chip semiconductor package according to claim 1, wherein the substrate further comprises a passive device.
